(19) United States
(12) Patent Application Publication
(10) Pub. No.: US 2025/0306093 A1
(43) Pub. Date: Oct. 2, 2025

(54) Periodic In-Field Testing of System on Chip Functional Units

(71) Applicants: Advanced Micro Devices, Inc, Santa Clara, CA (US); ATI Technologies ULC, Markham (CA)

(72) Inventors: Nehal R. Patel, Sunnyvale, CA (US); James Malcolm Wilson, San Diego, CA (US); Arie Lev Margulis, Richmond Hill (CA); Jeffrey Richard Rearick, Fort Collins, CO (US); Rajesh Ramesh Kapoor, El Dorado Hills, CA (US)

(21) Appl. No.: 18/621,472

(22) Filed: Mar. 29, 2024

(51) Int. Cl. G01R 31/28

(52) U.S. Cl. CPC G01R 31/2896; G01R 31/2856

(57) ABSTRACT

Periodic in-field testing of system on chip functional units is described. In accordance with the described techniques, a scan pattern associated with a fault is applied to a functional unit during an idle event of the functional unit, the scan pattern defining a sequence of input signals. An output of the functional unit is received in response to the scan pattern. A status of the functional unit with respect to the fault is output based on the output of the functional unit and an expected output for the scan pattern.

### BACKGROUND

A system on chip (SoC) is a device that consolidates multiple functional units on a single integrated circuit. SoCs have become extensively employed in diverse applications that utilize modern computing technologies, including high-performance data center servers, medical devices, and advanced automotive systems. The efficiency and dependability of these applications rely on efficient and accurate operation of the SoCs. For instance, data center servers providing cloud computing and data processing services rely on SoCs to deliver reliable high-speed performance to end-users. Defects or malfunctions in SoCs deployed within data center servers can potentially lead to performance bottlenecks/degradation, system downtime, and data loss. As another example, in automotive systems, SoCs are used in various vehicle control systems, and any defects in the SoCs can compromise the functionality, safety, and reliability of these vehicles. As such, there are stringent defective parts per million (DPPM) guidelines for SoCs used for these applications, and rigorous testing is performed on SoC components before the SoC leaves a silicon manufacturing facility.

### BRIEF DESCRIPTION OF THE DRAWINGS

FIG. 1 is a block diagram of a non-limiting example environment in which periodic in-field testing of system on chip functional units is implemented.

FIG. 2 depicts a non-limiting example of periodic testing of system on chip functional units.

FIG. 3 is a flow diagram depicting an algorithm as a step-by-step procedure in an example implementation of preparing a scan pattern payload for periodic in-field testing of system on chip functional units.

FIGS. 4A and 4B are a flow diagram depicting an algorithm as a step-by-step procedure in an example implementation of periodic in-field testing of system on chip functional units.

FIG. 5 is a flow diagram depicting an algorithm as a step-by-step procedure in another example implementation of periodic in-field testing of system on chip functional units.

### DETAILED DESCRIPTION

### Overview

As systems on chip (SoCs) have grown in complexity and functionality, there are increasing numbers of potential sites of degradation. For instance, some SoCs include millions or billions of transistors. Even though SoCs undergo rigorous structural and functional tests at a SoC vendor's facility before delivery to a customer, failures occur during use due to age-related degradation (e.g., parts wear out), environment-related degradation, and/or defects that escape the rigorous testing due to large number (e.g., billions) of potential defect sites.

As an example, silent data corruption occurs when defects in the SoC functional components (e.g., processing units) cause unintended alterations to data, such as due to incorrect computations, without an overt indication of the error when it occurs, and when it gets consumed. In the context of data centers, silent data corruption results in millions of dollars of lost revenue. In the context of advanced automotive systems and medical devices, silent data corruption results in unreliable device operation. Therefore, identifying defect bound parts in-field would enable degrading parts to be proactively replaced or repaired and reduce an impact of silent data corruption as well as part failure.

Existing techniques for identifying degraded SoC functional components include self-tests, such as a memory built-in self-test (BIST) and a logic BIST. These built-in self-tests are typically performed during a cold boot process. However, SoCs in many applications, such as in server applications and automotive applications, do not undergo frequent cold boot events. Instead, once the SoC completes the cold boot process, it remains on until the SoC reaches its end-of-life, some other failure occurs, or the SoC is taken offline for preventative maintenance. However, taking an SoC offline for preventative maintenance can result in revenue loss and other problems. Moreover, BISTs have reduced fault detection coverage as compared to automatic test pattern generation (ATPG) tests that are performed during manufacturing, resulting in undetected faults. As such, existing techniques for identifying in-field faults in SoC functional components are insufficient.

Periodic in-field testing of system on chip functional units is described herein. In one or more implementations, an in-field self-test is performed on a functional unit of an SoC while the functional unit is idle. The in-field self-test includes applying a scan pattern to the functional unit and comparing a response of the functional unit to an expected response in order to determine a status of the functional unit with respect to a fault associated with the scan pattern. In response to a fault being detected, in at least one variation, an alert is generated and communicated via a management controller.

In at least one example, the scan pattern is an ATPG pattern that is generated based on fault models for the SoC and/or the functional unit itself. The functional unit, for instance, is an intellectual property (IP) element that is integrated into the SoC in a modular fashion. Further, the functional unit is a pre-designed and pre-verified functional building block that is configured to provide a specific function or feature to the SoC. By way of example, the functional unit is a processing unit, such as a central processing unit (CPU).

In various implementations, fault models are received from a manufacturer of the SoC. For new technologies, for instance, fault models continually evolve, e.g., to address faults discovered as the technology is actually used in the field and/or as further testing is performed. The updated fault models enable the functional unit to be tested for newly identified faults (e.g., identified after the SoC was initially tested by the manufacturer) as well for new occurrences of previously identified faults.

In at least one implementation, a scan pattern payload which includes a plurality of scan patterns is generated by a SoC vendor in response to the SoC vendor receiving one or more updated fault models from the manufacturer of the SoC. Those scan patterns can be applied to a given functional unit one-by-one by a scan controller of the SoC. Performing the in-field self-test includes, in one or more implementations, applying the scan patterns of the scan pattern payload to the functional unit during one or more idle events.

Because the in-field self-test consumes substantial SoC bandwidth, the in-field self-test is performed at a pre-determined scheduled interval that is configured to balance the resource intensive process of the in-field self-test with the benefits of prompt fault detection. In at least one implementation, the in-field self-test is performed during an idle event that occurs after a threshold amount of time has passed since a previous in-field self-test.

By detecting in-field faults, an occurrence of silent data corruption is reduced, resulting in more reliable operation of the SoC and its larger system (e.g., a data center, automotive system, medical device, etc.) as a whole. Moreover, because the in-field self-test is opportunistically performed on individual functional units during idle events, an impact of testing for faults on system operation is reduced compared with external scans and preventative maintenance tests that are performed while the SoC is offline and/or shut down. Because the in-field self-test described herein uses updated fault models, a coverage and accuracy of the fault detection is increased, resulting in fewer undetected faults than existing self-testing techniques.

In some aspects, the techniques described herein relate to a system on chip, including a functional unit having a defined functional role for the system on chip, and a processor to execute instructions for an in-field self-test that causes the processor to apply a scan pattern associated with a fault to the functional unit during an idle event of the functional unit, the scan pattern defining a sequence of input signals, receive an output of the functional unit in response to the scan pattern, and output a status of the functional unit with respect to the fault based on the output of the functional unit and an expected output for the scan pattern.

In some aspects, the techniques described herein relate to a system on chip, wherein applying the scan pattern to the functional unit is in response to a self-test timer reaching a threshold amount of time while the idle event is detected.

In some aspects, the techniques described herein relate to a system on chip, wherein outputting the status of the functional unit with respect to the fault based on the output of the functional unit and the expected output for the scan pattern includes outputting a fail status in response to the output of the functional unit deviating from the expected output, and outputting a pass status in response to the output of the functional unit matching the expected output.

In some aspects, the techniques described herein relate to a system on chip, wherein the fail status indicates the fault is present in the functional unit, and the in-field self-test further causes the processor to generate an alert in response to outputting the fail status.

In some aspects, the techniques described herein relate to a system on chip, wherein the in-field self-test further causes the processor to copy the scan pattern from a mass storage location to a local memory of the system on chip by executing a scan pattern self-test application, and retrieve the scan pattern from the local memory during the idle event of the functional unit.

In some aspects, the techniques described herein relate to a system on chip, wherein the scan pattern self-test application is executed upon boot-up of the system on chip.

In some aspects, the techniques described herein relate to a system on chip, wherein applying the scan pattern associated with the fault to the functional unit during the idle event of the functional unit includes selecting the scan pattern from a plurality of scan patterns based on a value of a pattern counter, individual scan patterns of the plurality of scan patterns defining different sequences of input signals, and executing the sequence of input signals by a scan controller of the system on chip.

In some aspects, the techniques described herein relate to a system on chip, wherein receiving the output of the functional unit in response to the scan pattern includes recording, by the scan controller, the response of the functional unit to the sequence of input signals.

In some aspects, the techniques described herein relate to a system on chip, wherein the individual scan patterns of the plurality of scan patterns are associated with sequential numerical values, and wherein a numerical value associated with the scan pattern matches the value of the pattern counter.

In some aspects, the techniques described herein relate to a system on chip, wherein the scan pattern is included in a scan pattern payload that is generated based on fault models received from a manufacturer of the system on chip, and wherein the in-field self-test further causes the processor to isolate the functional unit from other functional units of the system on chip in response to detecting the idle event of the functional unit.

In some aspects, the techniques described herein relate to a method, including detecting an idle event of a functional unit of a system on chip, isolating the functional unit from other functional units of the system on chip in response to detecting the idle event, and while isolating the functional unit from the other functional units of the system on chip during the idle event and responsive to a threshold amount of time having passed since completing a scan pattern self-test at the functional unit capturing a response of the functional unit to at least one scan pattern of a plurality of scan patterns, and indicating a status of the functional unit with respect to a fault associated with the at least one scan pattern based on the response of the functional unit to the at least one scan pattern relative to an expected response.

In some aspects, the techniques described herein relate to a method, wherein individual scan patterns of the plurality of scan patterns are associated with sequential numerical values, and the method further includes tracking execution of the plurality of scan patterns across one or more idle events of the functional unit via a pattern counter.

In some aspects, the techniques described herein relate to a method, wherein tracking the execution of the plurality of scan patterns across the one or more idle events of the functional unit via the pattern counter includes executing the plurality of scan patterns in numerical order, and incrementing a number value of the pattern counter after executing a scan pattern of the plurality of scan patterns at the functional unit.

In some aspects, the techniques described herein relate to a method, wherein capturing the response of the functional unit to the at least one scan pattern of the plurality of scan patterns includes loading an individual scan pattern of the at least one scan pattern from a local memory storing the plurality of scan patterns to a scan controller of the system on chip, applying, by the scan controller, a series of input signals defined by the individual scan pattern to the functional unit, recording, by the scan controller, a series of output signals of the functional unit in response to the series of input signals, and, after recording the series of output signals by the scan controller, exiting the idle event in response to receiving a request to execute a task at the functional unit, or loading a subsequent individual scan pattern of the at least one scan pattern to the scan controller in response to not receiving the request to execute the task at the functional unit.

In some aspects, the techniques described herein relate to a method, further including copying the plurality of scan patterns from a mass storage location to a local memory of the system on chip in response to completion of a boot-up event of the system on chip, and updating the plurality of scan patterns in the mass storage location in response to receiving new fault models.

In some aspects, the techniques described herein relate to a system, including a system on chip including an intellectual property (IP) element, and a processor to execute instructions that cause the processor to detect an idle event of the IP element, isolate the IP element from other IP elements of the system on chip in response to detecting the idle event, and while isolating the IP element from the other IP elements of the system on chip during the idle event, perform a scan pattern self-test by executing at least one scan pattern of a scan pattern payload at the IP element responsive to a threshold amount of time having elapsed since previously completing the scan pattern self-test at the IP element, and indicating a status of the IP element with respect to a fault associated with the at least one scan pattern based on an output of the IP element to the at least one scan pattern relative to an expected output.

In some aspects, the techniques described herein relate to a system, wherein the threshold amount of time is determined based on a saturation of a self-test timer associated with the IP element, the self-test timer configured to reset upon completion of the scan pattern self-test.

In some aspects, the techniques described herein relate to a system, wherein the completion of the scan pattern self-test includes executing every scan pattern of the scan pattern payload over one or more idle events of the IP element.

In some aspects, the techniques described herein relate to a system, wherein the instructions further cause the processor to track execution of the at least one scan pattern via a pattern counter associated with the IP element.

In some aspects, the techniques described herein relate to a system, further including a local memory communicatively coupled to the system on chip and storing the scan pattern payload, and wherein the instructions further cause the processor to load an individual scan pattern of the at least one scan pattern from the local memory to the system on chip, apply, via a scan controller of the system on chip, a sequence of input signals defined by the individual scan pattern to the IP element, and record, by the scan controller, the output of the IP element to the individual scan pattern as a sequence of output signals.

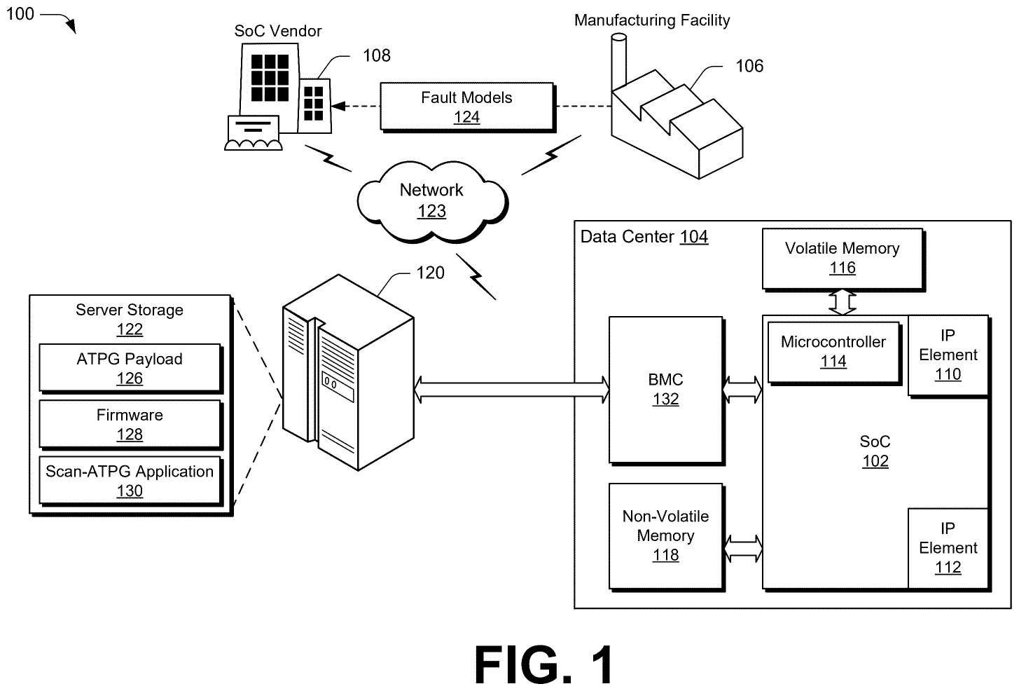

FIG. 1 is a block diagram of a non-limiting example environment 100 in which periodic in-field testing of system on chip functional units is implemented. In particular, the environment 100 includes a system on chip (SoC) 102. In one or more implementations, the SoC 102 is a component of a data center 104. For instance, the SoC 102 is manufactured at a manufacturing facility 106 (e.g., a foundry), and a SoC vendor 108 receives the SoC 102 from the manufacturing facility 106 and completes a series of structural and functional tests on the SoC 102. The structural and functional tests include, for example, burn-in tests (where the SoC 102 is operated at a high voltage and frequency), board-level tests, and automatic test pattern generation (ATPG) tests. The ATPG tests include applying sequences of input values to a circuit of the SoC 102 to simulate a response to the sequences in order to identify specific faults in the circuit. As an example, a given ATPG pattern, also referred to herein as a scan pattern, is associated with a particular fault possible in the circuit, such as a stuck-in fault (where a signal is permanently stuck at “0” or “1”), a bridging fault (where two signals are shorted together), or another type of logical fault. If execution of the ATPG pattern detects a fault, a location of the fault is identified so that the SoC vendor 108 is able to diagnose and rectify the issue prior to delivery of the SoC 102 to the data center 104. Although the non-limiting example environment 100 shows the SoC 102 included in the data center 104, it is to be appreciated that in variations, the SoC 102 is included in another environment that utilizes SoCs for computing processes, such as an automotive system or a medical device.

In the non-limiting example environment 100, the SoC 102 includes a plurality of functional units, depicted in FIG. 1 as an IP element 110 and an IP element 112. The functional units (e.g., functional blocks) are hardware components that include pre-designed and pre-verified intellectual property (IP) elements that are configured to provide a specific functional role or feature to the SoC 102. Examples of functional units include a central processing unit (CPU) core, a memory controller, a peripheral, an interface (e.g., a sensor interface, a display interface, a communication interface, a network interface, etc.), a cache (or cache hierarchy), or the like. Additional examples of the functional units include a graphics processing unit (GPU), an accelerator, and a signal processor (such as image signal processor, an audio signal processor, or another type of digital signal processor). For example, the functional units are modular hardware components that are integrated into the SoC 102. In one or more implementations, the functional units include a semiconductor material (e.g., silicon) having conductive (e.g., metal) and insulating (e.g., dielectric) layers deposited or otherwise disposed thereon in a pattern that provides a desired functionality. By integrating pre-designed and pre-verified functional units into the SoC 102, the manufacturing facility 106 reduces a manufacturing time and expense, for example.

In one or more implementations, the SoC 102 includes logic for creating per-IP isolations. This logic enables the IP element 110 and the IP element 112 to be individually powered down when a respective IP element is idle, e.g., to save power. In accordance with the techniques described herein, the per-IP isolation functionality is leveraged to perform ATPG testing on IP elements while the SoC 102 is in-field at the data center 104 and in use.

The SoC 102 further includes a microcontroller 114. The microcontroller 114 includes functionality for executing control and processing tasks within the SoC 102. The microcontroller 114, for instance, controls the overall operation of the SoC 102. As a part of this functionality, the microcontroller 114 detects IP element idle activity and coordinates the in-field fault testing of the idle IP element, as will be elaborated below.

The SoC 102 is communicatively coupled to volatile memory 116 and/or to non-volatile memory 118. Examples of the volatile memory 116 include random-access memory (RAM), dynamic random-access memory (DRAM), synchronous dynamic random-access memory (SDRAM), and static random-access memory (SRAM). Examples of the non-volatile memory 118 include solid state disks (SSD), flash memory, read-only memory (ROM), programmable read-only memory (PROM), erasable programmable read-only memory (EPROM), and electronically erasable programmable read-only memory (EEPROM). The volatile memory 116 provides local storage for the SoC 102, for instance, whereas the non-volatile memory 118 stores an operating system and one or more applications executed on the SoC 102. In one or more implementations, the volatile memory 116 and the non-volatile memory 118 are communicatively coupled to the SoC 102 via a wired communication interface, such as a peripheral component interconnect express (PCIe), a universal serial bus (USB), or Ethernet. The volatile memory 116 and the non-volatile memory 118 are configurable in a variety of ways without departing from the spirit or scope of the described techniques.

In one or more implementations, the SoC vendor 108 maintains and/or otherwise accesses a server 120, which includes server storage 122. By way of example, the server 120 is a shared computing resource that is accessible by the SoC vendor 108 and a plurality of SoC users (e.g., customers), including the data center 104, via a network 123. In at least one variation, however, the server 120 is included in the data center 104. In one or more implementations, the SoC vendor 108 receives fault models 124 from the manufacturing facility 106, such as by the manufacturing facility 106 sending the fault models 124 to the SoC vendor 108 via a network 123 when the fault models 124 have been updated. In at least one variation, the SoC vendor 108 requests the fault models 124 from the manufacturing facility 106 (e.g., via the network 123) in an on-demand basis. By way of example, the fault models 124 include a latest, updated set of faults identified by the manufacturing facility 106. The manufacturing facility 106, for instance, identifies new fault models over time, after the SoC 102 is already shipped to a customer (e.g., the data center 104) by the SoC vendor 108, and these new fault models are included in the fault models 124 communicated to the SoC vendor 108. The new fault models are identified by the manufacturing facility 106 based on failure diagnoses of returned parts, for instance, which enable the manufacturing facility 106 to analyze the faults and tune the testing process to increase yield, quality, and reliability.

The SoC vendor 108 processes the fault models 124 and generates an ATPG payload 126 and firmware 128 based on the fault models 124. The ATPG payload 126 includes a plurality of ATPG patterns that are configured to enable faults of the fault models 124, including new and/or updated fault models, to be detected. The firmware 128 includes instructions that enable the SoC 102 to orchestrate and execute the ATPG patterns in the ATPG payload 126. The ATPG payload 126 and the firmware 128 are stored in the server storage 122, for instance, which provides a mass storage location that is accessible by the SoC 102 as well as other SoCs of the data center 104.

In at least one implementation, an application executing on the server 120 prepares the ATPG payload 126 from the fault models 124, such as by performing test generation algorithms that use the fault models 124 to generate scan patterns (e.g., ATPG patterns) that will detect these faults. In one or more implementations, generating the ATPG payload 126 includes compressing and encrypting the generated scan patterns. Additionally or alternatively, the generated scan patterns are verified via fault simulation techniques to ensure that the generated scan patterns cover the fault models 124 before the ATPG payload 126 is copied to the server storage 122. The ATPG payload 126 and the firmware 128 are periodically refreshed as the manufacturing facility 106 provides updated fault models 124.

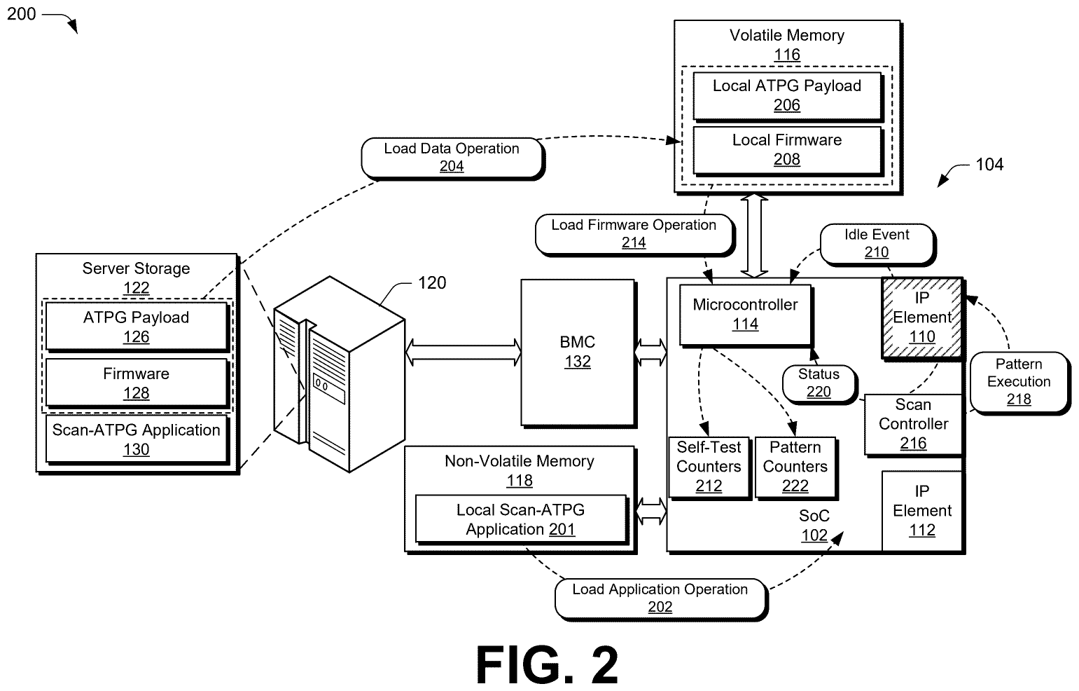

In at least one implementation, the SoC vendor 108 further generates and/or updates a scan-ATPG application 130 based on updates to the ATPG payload 126 and/or the firmware 128. In one or more implementations, the scan-ATPG application 130 is an operating system application that is stored in the server storage 122 and configured to be loaded to and executed at the SoC 102 upon completion of a cold boot event. As will be elaborated below with respect to FIG. 2, once the cold boot event is complete and the operating system takes control of the SoC 102, a local copy of the scan-ATPG application 130 is initiated at the SoC 102. The scan-ATPG application 130 includes instructions for allocating configurable memory space in the volatile memory 116 for at least a portion of the ATPG payload 126 and the firmware 128. The scan-ATPG application 130 further includes instructions for coordinating the various hardware components of the data center 104 in performing the in-field fault testing using the ATPG payload 126.

The data center 104 further includes a baseboard management controller (BMC) 132. The BMC 132 includes functionality for managing and monitoring the data center 104, including the server 120 and the SoC 102. The BMC 132, for instance, is configured to generate alerts and log events related to a status and health of the SoC 102. The alerts are output to an administrator of the data center 104, for example, and the logged events are viewable by the administrator. In at least one implementation, the BMC 132 stores the events in an off-chip database and enables the analysis of events and testing instances. As will be elaborated herein, the BMC 132 is usable to output alerts regarding in-field fault detection at the IP elements.

FIG. 2 depicts a non-limiting example 200 of periodic testing of system on chip functional units. The illustrated example 200 includes the data center 104 from FIG. 1, including the SoC 102, the volatile memory 116, the non-volatile memory 118, and the BMC 132, and other associated components introduced with respect to FIG. 1. The illustrated example 200 further includes the server 120 from FIG. 1, including the server storage 122 and the ATPG payload 126, the firmware 128, and the scan-ATPG application 130 stored thereon.

In the non-limiting example 200, the non-volatile memory 118 of the SoC 102 stores a local copy of the scan-ATPG application 130, depicted in FIG. 2 as a local scan-ATPG application 201. By way of example, the scan-ATPG application 130 is copied from the server storage 122 and stored in the non-volatile memory 118 as the local scan-ATPG application 201. The local scan-ATPG application 201 is an executable copy of the scan-ATPG application 130 (e.g., executable by the SoC 102) that facilitates in-field testing of the SoC 102. The local scan-ATPG application 201 further includes functionality to check for updates to the ATPG payload 126, the firmware 128, and/or the scan-ATPG application 130 stored in the server storage 122, as will be elaborated below.

A load application operation 202 is performed, for example, after an on-die bootloader executes on the SoC 102 and an operating system becomes active. In one or more implementations, following boot-up, the operating system loads the local scan-ATPG application 201 via the load application operation 202. Once loaded, local scan-ATPG application 201 connects to the server storage 122 (e.g., via the network 123 shown in FIG. 1) and performs a load data operation 204 to copy the ATPG payload 126 and the firmware 128 to the volatile memory 116, creating a local ATPG payload 206 and local firmware 208. By way of example, the BMC 132 fetches the ATPG payload 126 and the firmware 128 from the server storage 122 and loads it into the volatile memory 116 during the load data operation 204. In at least one implementation, a subset of the ATPG patterns included in the ATPG payload 126 is downloaded and stored in the local ATPG payload 206, depending on an amount of storage space available in the volatile memory 116. Moreover, in at least one implementation, the ATPG payload 126 and the firmware 128 are encrypted for security purposes during the load data operation 204. It is to be appreciated that the local scan-ATPG application 201 includes functionality to periodically check the server storage 122 for updates to the ATPG payload 126, the firmware 128, and/or the scan-ATPG application 130 so that the local scan-ATPG application 201, the local ATPG payload 206, and the local firmware 208 are updated accordingly. By way of example, the local scan-ATPG application 201 sends a query to the server storage 122 to check for updates to the ATPG payload 126, the firmware 128 and/or the scan-ATPG application 130 at a pre-determined frequency, such as daily, weekly, biweekly, monthly, or the like. In at least one variation, alternatively or in addition, the server storage 122 communicates that updates are available without the local scan-ATPG application 201 sending an explicit request.

During operation of the SoC 102, individual functional units become idle. In the non-limiting example 200, the IP element 110 is idle, as indicated by a diagonal fill pattern, whereas the IP element 112 remains active and executing assigned workload tasks, e.g., for executing additional applications other than the local scan-ATPG application 201. The microcontroller 114 detects an idle event 210 of the IP element 110, which indicates that the IP element 110 is available for in-field testing. In one or more implementations, the microcontroller 114 enables the isolation of the IP element 110 from the IP element 112 (as well as other IP elements of the SoC 102) to prepare for the in-field testing. Additionally or optionally, the microcontroller 114 saves content of the IP element 110 in the volatile memory 116 so that the content is restored at the IP element 110 when the idle event 210 ends.

In response to detecting the idle event 210, the microcontroller 114 references self-test counters 212, which include at least one counter that tracks a frequency at which the in-field testing has been performed and/or completed for a given IP element. The self-test counters 212, for instance, include separate counters for individual IP elements of the SoC 102. By way of example, a self-test counter for the IP element 110 resets upon completion of the in-field testing at the IP element 110 and is used by the microcontroller 114 to determine if at least a threshold amount of time has passed before again executing the in-field testing at the IP element 110 The in-field testing is also referred to herein as a self-test because the testing is performed using components of the SoC 102 itself, rather than external components and scan controllers.

The threshold amount of time is a configurable time duration that is set by the local firmware 208 according to a desired frequency of the in-field testing (e.g., daily, weekly, biweekly, monthly, or the like) for a given technology node. For example, performing ATPG scans too frequently ties up bandwidth on the SoC 102, whereas performing the ATPG scan too infrequently delays fault detection. As a non-limiting example, the self-test counters 212 are slow frequency clocks (e.g., below 100 megahertz) that increment with respect to time until becoming saturated when the threshold amount of time is reached. The slow frequency reduces power consumption, for instance. In such an example, the microcontroller 114 determines that the threshold amount of time has passed in response to detecting saturation of a respective one of the self-test counters 212.

In response to the microcontroller 114 determining, based on the self-test counters 212, that the threshold amount of time has not elapsed (e.g., the self-test counter for the IP element 110 is not saturated), then the self-test is not performed on the IP element 110. For instance, the IP element 110 is shut down to reduce power. On the other hand, in response to the microcontroller 114 determining, based on the self-test counters 212, that the threshold amount of time has passed since performance and/or completion of the previous self-test, a load firmware operation 214 is performed by the microcontroller 114 to load the local firmware 208 from the volatile memory 116. The microcontroller 114 then executes at least a portion of the local firmware 208 to commence the periodic self-test. Execution of the local firmware 208, for instance, causes the local ATPG payload 206 to be read from the volatile memory 116. In at least one implementation, reading the local ATPG payload 206 from the volatile memory 116 includes authenticating the local ATPG payload 206. In response to successful authentication via execution of the local firmware 208, the local ATPG payload 206 is decompressed, decrypted, and delivered to a scan controller 216 of the SoC 102 for execution. In contrast, the process is exited if the authentication fails.

In accordance with the described techniques, pattern execution 218 is performed by the scan controller 216. The scan controller 216 includes functionality of the SoC 102 for performing built-in self-tests, e.g., during cold booting. The scan controller 216, for instance, is configured to control and manage scan-based testing on the SoC 102. In one or more implementations, the pattern execution 218 includes loading, by executing the local firmware 208 on the SoC 102, an individual pattern from the local ATPG payload 206 to the scan controller 216 and applying, by the scan controller 216, the individual ATPG pattern to the IP element 110 (or another IP of the SoC 102 that is undergoing the self-test). By way of example, based on instructions of the local firmware 208, the scan controller 216 applies the ATPG patterns of the local ATPG payload 206 to the IP element 110 one-by-one and captures the response (e.g., an output of the IP element 110) to the individually applied ATPG patterns.

The pattern execution 218 includes recording an actual response of the IP element 110 to individual patterns in order to enable the actual response to be compared to an expected response. This comparison results in a status 220. The status 220, for instance, is a pass/fail status based on whether the actual response matches the expected response (pass) or not (fail). A fault is detected in response to the actual response not matching the expected response, with a type of the fault determined based on the fault model used to generate the corresponding ATPG pattern.

In one or more implementations, the ATPG patterns are applied one-by-one until all of the ATPG patterns in the local ATPG payload 206 have been tested or until the microcontroller 114 detects that the IP element 110 is to exit the idle event 210, such as in response to receiving an interrupt signal from the operating system. In an example scenario, a portion of the ATPG patterns of the local ATPG payload 206 are executed during the idle event 210, and so a remaining portion of the ATPG patterns of the local ATPG payload 206 remain to be executed during a subsequent idle event in order to complete the self-test.

Accordingly, in at least one implementation, pattern counters 222 are used to track which ATPG patterns have been performed. The pattern counters 222 include at least one counter that tracks execution of the ATPG patterns of the local ATPG payload 206 at a given IP element. By way of example, a first pattern counter is associated with the IP element 110 and resets upon completion of the ATPG patterns of the local ATPG payload 206 at the IP element 110, and a second pattern counter is associated with the IP element 112 and resets upon completion of the ATPG patterns of the local ATPG payload 206 at the IP element 112. For instance, the ATPG patterns of the local ATPG payload 206 are associated with sequential numerical values, and the self-test executes the ATPG pattern in numerical order, with the corresponding one of the pattern counters 222 incrementing for each successive pattern, until the pattern counter saturates in response to all of the ATPG patterns of the local ATPG payload 206 being executed at the given IP element. When the self-test is interrupted before the corresponding one of the pattern counters 222 saturates, a subsequent self-test begins with the next ATPG pattern in numerical order according to the value of the pattern counter.

Although the self-test counters 212 and the pattern counters 222 are depicted on the SoC 102, it is to be appreciated that variations are possible. In one or more variations, the self-test counters 212 and/or the pattern counters 222 are implemented as software-based counters, such as via the scan-ATPG application 130. Additionally, or alternatively, the self-test counters 212 and/or the pattern counters 222 are hardware-based counters included in the microcontroller 114 or the BMC 132, for instance.

In this way, via the status 220, any detected faults are reported to the BMC 132 so that an administrator is alerted to a potential fault of the SoC 102. Using this error information, the administrator is able to perform additional diagnostics to determine a cause of the fault, put an associated part in a quarantine pool, and so for. By performing the periodic in-field testing, the scan patterns based on the newest fault models 124 from the manufacturing facility 106 are executed by the SoC 102 without returning the SoC 102 to the SoC vendor 108 or shutting down the SoC 102 for maintenance. By using the newest fault models 124, enhanced fault detection is provided with increased detection accuracy. Moreover, by leveraging the idle event 210, the self-test described herein facilitates detection of faults without downtime or negative impacts on revenue of the data center 104, as the SoC 102 remains online and active. By efficiently and opportunistically testing for faults in-field and while the SoC 102 is operational according to the techniques described herein, an impact on silent data corruption at the data center 104 is reduced.

Additionally, reporting a status 220 of “pass” to the BMC 132 enables the BMC 132 to log that the test was performed, a time of the test, and an indication that the corresponding functional unit (e.g., the IP element 110) passed in order to enable relative relationships between operational events and the status 220 to be determined. Doing so enables the administrator to identify any changes that have occurred to an operational state of the SoC 102, including environmental changes, between the status 220 changing from a pass to a fail, for instance. Moreover, by loading the local ATPG payload 206 and the local firmware 208 to the SoC 102 rather than from the server storage 122, a latency of performing the in-field testing is reduced, e.g., by reducing or eliminating a test insertion time overhead. Reducing the latency is advantageous due to a relatively small amount of time during which the IP element 110 is idle, at least in some use cases, thus enabling the self-test to be completed more efficiently.

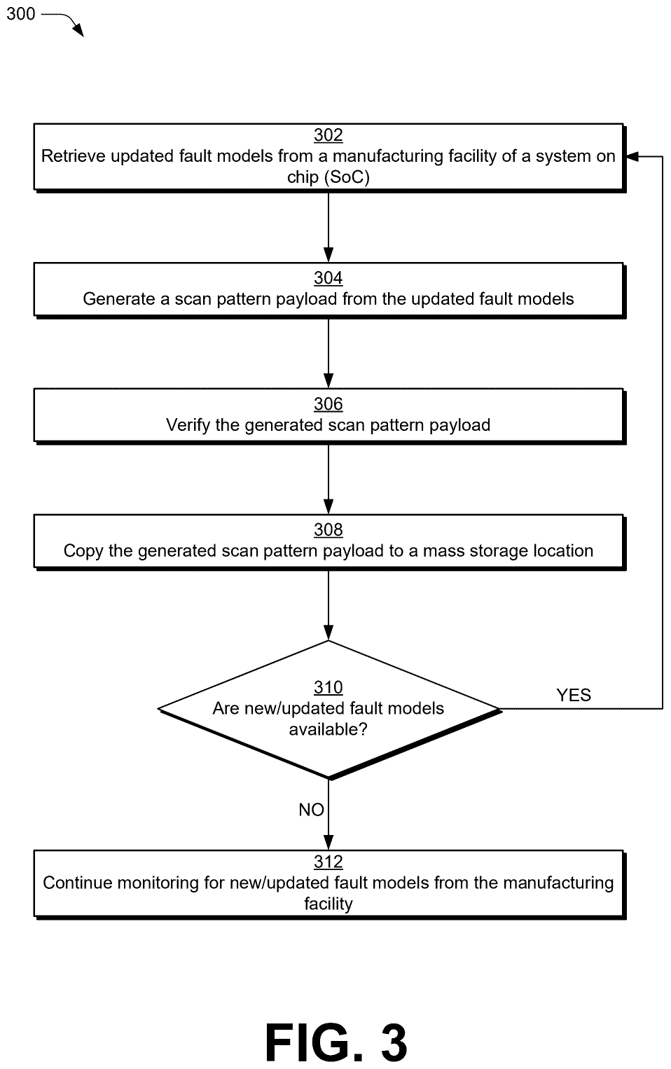

FIG. 3 is a flow diagram depicting an algorithm as a step-by-step procedure 300 in an example implementation of preparing a scan pattern payload for periodic in-field testing of system on chip functional units. In one or more implementations, the step-by-step procedure 300 is executed, at least in part, by components of the non-limiting example environment 100 of FIG. 1. As such, where appropriate, reference will be made to components previously introduced in FIG. 1.

Updated fault models are retrieved from a manufacturing facility of a system on chip (SoC) (block 302). By way of example, the updated fault models (e.g., the fault models 124) correspond to new and/or enhanced fault models identified by the manufacturing facility 106 of the SoC 102, after production and testing of the SoC 102 by the SoC vendor 108 and delivery of the SoC 102 to the data center 104 (e.g., an owner of the SoC 102). Additionally or alternatively, the updated fault models include a most recent version of fault models that the SoC 102 has already been tested for by the SoC vendor 108 prior to delivery to the data center 104.

A scan pattern payload is generated from the updated fault models (block 304). By way of example, an application executing on a server of the SoC vendor 108 (e.g., the server 120) prepares the scan pattern payload (e.g., the ATPG payload 126) from the updated fault models via test generation algorithms that generate scan patterns (e.g., ATPG patterns) that are configured to detect faults included in the updated fault models. These generated scan patterns are included in the scan pattern payload.

The generated scan pattern payload is verified (block 306). By way of example, the scan patterns of the generated scan pattern payload are verified via fault simulation techniques to ensure the generated scan patterns are usable to accurately detect the faults of the updated fault models. In one or more implementations, in response to the expected faults not being detected via the simulation, one or more of the scan patterns are regenerated. For instance, a scan pattern for a stuck-in fault that does not detect the stuck-in fault during the fault simulation is discarded and regenerated or adjusted.

The generated scan pattern payload is copied to a mass storage location (block 308). By way of example, once verified, the generated scan pattern payload is copied to the mass storage location so that multiple networked devices have access to the generated scan pattern payload for in-field testing. In one or more implementations, the mass storage location is the server storage 122 of the server 120.

It is determined if new/updated fault models are available (block 310). By way of example, the server 120 and/or the SoC vendor 108 includes functionality for periodically checking for new updates to the fault models from the manufacturing facility 106. For instance, the server 120 sends a request to the manufacturing facility 106 to receive updates, if available, at a predetermined frequency, such as weekly, biweekly, monthly, quarterly, or the like. Alternatively, or in addition, the manufacturing facility 106 sends new/updated fault models to the server 120 (e.g., via the SoC vendor 108) as they are identified and without receiving an explicit request from the server 120 and/or the SoC vendor 108. If new/updated fault models have been provided by the manufacturing facility 106, the updated fault models are retrieved (block 302), such as described above. If new/updated fault models have not been provided, monitoring for new/updated fault models from the manufacturing facility is continued (block 312). Once generated and copied to the mass storage device, the existing scan pattern payload is made available for use in periodic in-field testing of the SoC, such as described in detail with respect to FIGS. 2 and 4A-5.

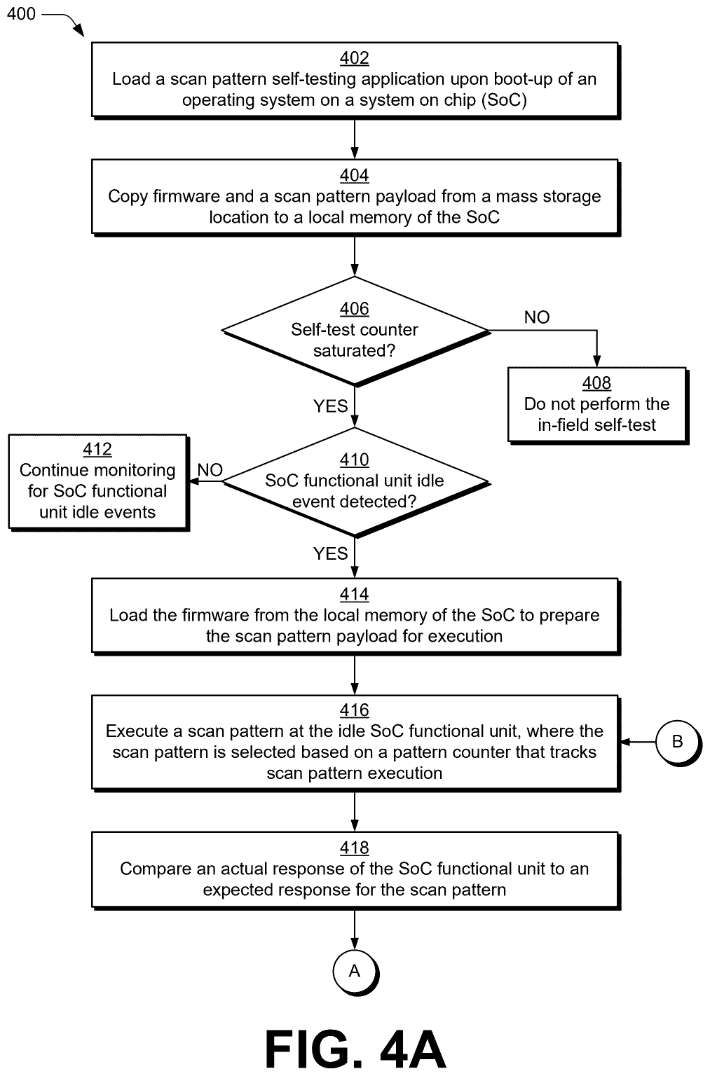

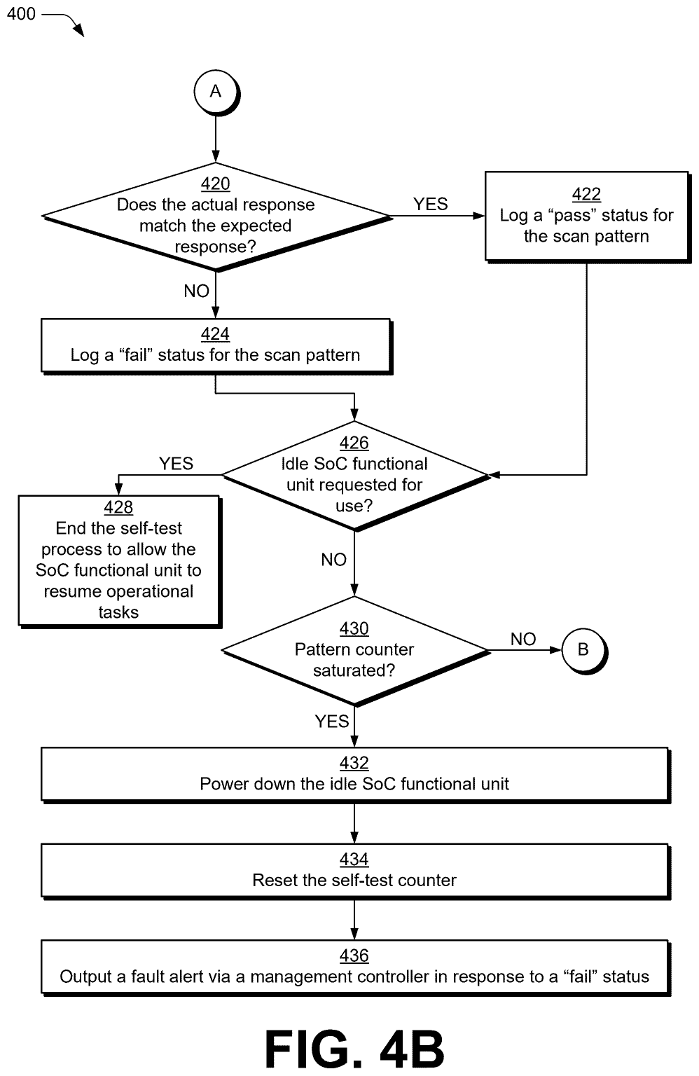

FIGS. 4A and 4B are a flow diagram depicting an algorithm as a step-by-step procedure 400 in an example implementation of periodic in-field testing of system on chip functional units. In one or more implementations, the step-by-step procedure 400 is implemented as instructions that are executed, at least in part, by components of the data center 104 of FIGS. 1 and 2, including a processor of the SoC 102 (e.g., the microcontroller 114). As such, where appropriate, reference will be made to components previously introduced in FIGS. 1 and 2. The step-by-step procedure 400 is shown as a set of blocks that specify operations performed by one or more devices and are not limited to the orders shown for performing the operations by the respective blocks.

Referring first to FIG. 4A, a scan pattern self-testing application is loaded upon boot-up of an operating system on a system on chip (SoC) (block 402). By way of example, the scan pattern self-testing application is loaded (e.g., via the load application operation 202) after an on-die bootloader executes on the SoC 102 and the operating system becomes active. In at least one implementation, the scan pattern self-testing application is stored in the non-volatile memory 118, e.g., as the local scan-ATPG application 201. For instance, the local scan-ATPG application 201 is a local copy of the scan-ATPG application 130, which is updated and maintained by the SoC vendor 108 in the server storage 122.

Firmware and a scan pattern payload are copied from a mass storage location to a local memory of the SoC (block 404). By way of example, the scan pattern self-testing application (e.g., the local scan-ATPG application 201) connects to the mass storage location via a wired and/or wireless communication technique and sends a query for new patterns. If new patterns are detected, the scan pattern self-testing application performs a load data operation 204 to copy the scan pattern payload (e.g., the ATPG payload 126) and the firmware (e.g., the firmware 128) to the local memory, creating a local copy of the scan pattern payload (e.g., the local ATPG payload 206) and a local copy of the firmware (e.g., the local firmware 208). In one or more implementations, the mass storage location is the server storage 122 of the server 120, and the local memory is the volatile memory 116. In at least one implementation, the BMC 132 fetches the ATPG payload 126 and the firmware 128 from the server storage 122 and loads it into the volatile memory 116 during the load data operation 204.

In scenarios where a storage capacity of the local memory is less than can hold the scan pattern payload stored in the mass storage location, a subset of the scan patterns of the scan pattern payload is downloaded and stored in the local scan pattern payload. For instance, the scan pattern self-testing application downloads a pre-determined number or data size of scan patterns that are selected to maintain coverage of a greatest number of faults with a highest coverage. Moreover, in at least one implementation, the scan pattern payload is encrypted during the load data operation 204.

It is determined if a self-test counter is saturated (block 406). By way of example, the self-test counter is specific for a particular functional unit of the SoC 102 in order to individually track how long it has been since that particular functional unit has undergone an in-field self-test. The functional units are hardware components that include pre-designed and pre-verified functional blocks that are integrated into to the SoC 102, such as the IP element 110 and the IP element 112 depicted in FIG. 1. For instance, a first self-test counter is associated with the IP element 110, and a second self-test counter is associated with the IP element 112. In at least one implementation, the self-test counter resets to zero when the in-field self-test is completed for the associated functional unit and increments according to time until becoming saturated at a threshold amount of time corresponding to a desired in-field self-test frequency. The threshold amount of time is configurable and set by firmware according to a desired frequency of in-field testing (e.g., daily, weekly, biweekly, monthly, or the like), such as discussed above with respect to FIG. 2.

If the self-test counter is not saturated, the in-field self-test is not performed (block 408). By way of example, when the self-test counter is not saturated, less than the threshold amount of time has passed since the previous self-test was performed. As such, execution of the self-test is not indicated, as testing too frequently ties up bandwidth on the SoC 102. In at least one implementation, performing the self-test a given functional unit prevents applications executing on the SoC 102 from requesting usage of the functional unit, at least while a scan pattern is being executed. It is to be appreciated that the step-by-step procedure 400 includes continuing to monitor for saturation of the self-test counter.

In contrast, in response to the self-test counter being saturated, it is determined if a SoC functional unit idle event is detected (block 410). By way of example, a microcontroller of the SoC (e.g., the microcontroller 114) monitors for idle events of individual functional units of the SoC. During operation of the SoC 102, a functional unit becomes idle when it is not being used to execute application tasks, for example.

If the SoC functional unit idle event is not detected, monitoring for SoC functional unit idle events is continued (block 412). On the other hand, in response to the SoC functional unit idle event being detected, the firmware is loaded from the local memory of the SoC to prepare the scan pattern payload for execution (block 414). By way of example, the local firmware is loaded to the microcontroller 114 for execution. The local firmware, for instance, includes instructions for decompressing and decrypting the scan pattern payload. As such, in at least one implementation, preparing the scan pattern payload for execution includes decompressing and unencrypting the scan pattern payload. Additionally or alternatively, preparing the scan pattern payload for execution includes authenticating the scan pattern payload.

A scan pattern is executed at the idle SoC functional unit, where the scan pattern is selected based on a pattern counter that tracks scan pattern execution (block 416). By way of example, executing the scan pattern at the idle SoC functional unit includes applying the scan pattern to the idle SoC functional unit by a scan controller (e.g., the scan controller 216) according to instructions of the local firmware. Execution of the local firmware by the microcontroller, for instance, causes one scan pattern of the scan pattern payload to be sent to the scan controller at a time, and the scan controller applies the one scan pattern and records a response (e.g., output) of the functional unit. The scan patterns include, for instance, different sequences of input signals or values (e.g., ones and zeros), and the scan controller applies the corresponding sequence of input signals to the idle SoC functional unit and records the response of the idle SoC functional unit to the sequence of input signals.

In one or more implementations, the pattern counter is specific to an individual functional unit of the SoC 102 in order to individually track which scan patterns have been executed on the associated functional unit. For instance, a first pattern counter is associated with the IP element 110, and a second pattern counter is associated with the IP element 112. In at least one implementation, the scan patterns in the local scan pattern payload are associated with sequential numerical values, and the scan patterns are executed by the scan controller in numerical order, with the pattern counter incrementing for each successive scan pattern. As such, if a portion of the scan patterns are applied during a given execution of the in-field self-test, the pattern counter tracks which scan pattern to begin with during a subsequent execution of the in-field self-test at the associated functional unit. In this way, an entirety of the scan pattern payload is completed over one or more idle events of the functional unit.

An actual response of the SoC functional unit to the scan pattern is compared to an expected response for the scan patterns (block 418). By way of example, the actual response of the SoC functional unit to a given scan pattern of the scan pattern payload is compared to its corresponding expected response in order to determine if the actual response matches the expected response. A match occurs when there are no errors in the actual response. In contrast, errors occur due to fault-related defects of the SoC functional unit. As such, the comparison enables a presence or absence of a fault associated with the given scan pattern to be detected.

Referring to FIG. 4B, it is determined if the actual response matches the expected response (block 420). If the actual response matches the expected response, a “pass” status is logged for the scan pattern (block 422). By way of example, the “pass” status indicates that the fault associated with the given scan pattern is not present in the SoC functional unit, at least at the time the given scan pattern was applied. The “pass” status includes a timestamp, for instance. In one or more implementations, a management controller (e.g., the BMC 132) stores the “pass” status in an off-chip database to enable additional analyses to be performed on in-field self-test data. Alternatively, or in addition, the “pass” status is stored in a log or results table.

In response to the actual result not matching the expected result, a “fail” status is logged for the scan pattern (block 424). By way of example, the “fail” status indicates that the fault associated with the given scan pattern is present in the SoC functional unit. In one or more implementations, the management controller also stores the “fail” status in the off-chip database. Alternatively, or in addition, the “fail” status is stored in the log or results table.

It is determined if the idle SoC functional unit is requested for use (block 426). By way of example, the microcontroller 114 receives an interrupt communicated by the operating system in response to the idle SoC functional unit being requested for use, e.g., by an application for processing tasks. If the idle SoC functional unit is requested for use, the self-test process is ended to allow the SoC functional unit to resume operational tasks (block 428). By way of example, a current scan process for a currently applied scan pattern is completed, and the pattern counter stores the numerical value associated with the most recently executed scan pattern. A subsequent scan pattern is not loaded to the scan controller. Instead, the SoC functional unit becomes operational for use in processing tasks.

If the idle SoC functional unit is not requested for use, it is determined if the pattern counter is saturated (block 430). By way of example, the pattern counter saturates when all of the scan patterns of the scan pattern payload have been executed by the scan controller. In contrast, the pattern counter is not saturated when there are scan patterns of the scan pattern payload have not been executed by the scan controller during a current iteration of the in-field self-test. Due to the interrupt process described above, it is to be appreciated that a single iteration of the in-field self-test occurs during one or more idle events.

If the pattern counter is not saturated, a subsequent scan pattern is selected based on the pattern counter and executed at the idle functional unit, e.g., by returning to the block 416 (see FIG. 4A). In this way, the scan controller applies the scan patterns of the scan pattern payload to the idle SoC functional unit one-by-one until either the idle event ends or the pattern counter saturates, indicating completion of the scan pattern payload.

If the pattern counter is saturated, the idle SoC functional unit is powered down (block 432). By way of example, the idle SoC functional unit is no longer undergoing the in-field self-test and is also not being used for processing tasks. As such, the idle SoC functional unit is powered down to conserve energy.

The self-test counter is reset (block 434). By way of example, the self-test counter is reset upon completion of the scan pattern payload so that the in-field self-test is again performed when the self-test counter is subsequently saturated, such as discussed above with respect to the block 406. Moreover, the pattern counter is reset so that the scan pattern payload is restarted from the beginning (e.g., at the lowest numerical value) during the subsequent execution of the in-field self-test.

A fault alert is output via a management controller in response to a “fail” status (block 436). By way of example, the fault alert includes an error report that identifies the detected fault (or faults, when more than one is present), a location of the fault, and so forth. In one or more implementations, the management controller outputs the fault alert in response to recording the “fail” result. The fault alert is output to an administrator (e.g., of the data center 104), for instance, via a user interface. Communication of the fault alert by the BMC 132 enables the administrator can take any warranted action, such as running diagnostics and/or putting the tested SoC functional unit (or the SoC 102 itself) into a quarantine pool.

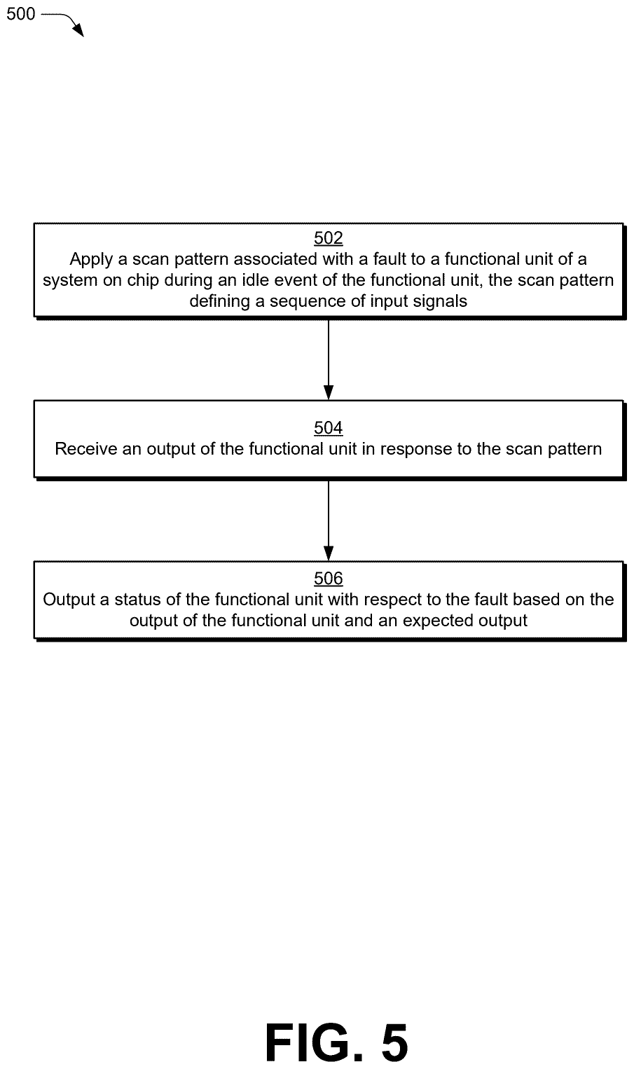

FIG. 5 is a flow diagram depicting an algorithm as a step-by-step procedure 500 in another example implementation of periodic in-field testing of system on chip functional units. In one or more implementations, the step-by-step procedure 500 is implemented as instructions that are executed, at least in part, by components of the data center 104 of FIGS. 1 and 2, including a processor of the SoC 102 (e.g., the microcontroller 114). As such, where appropriate, reference will be made to components previously introduced in FIGS. 1 and 2. Moreover, in at least one implementation, the step-by-step procedure 500 is a high-level variation of the step-by-step procedure 400 depicted in FIGS. 4A and 4B.

A scan pattern associated with a fault is applied to a functional unit of a system on chip during an idle event of the functional unit, the scan pattern defining a sequence of input signals (block 502). By way of example, the scan pattern is included in a scan pattern payload that is generated by the SoC vendor 108 from the fault models 124 received from the manufacturing facility 106 and stored locally in the volatile memory 116. In one or more implementations, applying the scan pattern to the functional unit includes loading the scan pattern to a scan controller of the system on chip and executing the sequence of input signals by the scan controller. In accordance with the techniques described herein, the scan pattern is selected from a plurality of scan patterns of the scan pattern payload based on a value of a pattern counter that tracks which of the plurality of scan patterns have already been executed, e.g., by counting up. For instance, individual scan patterns of the plurality of scan patterns are associated with sequential numerical values and include different sequences of input signals. The scan pattern is selected in response to its associated numerical value matching the value of the pattern counter. In at least one variation, the scan pattern is selected in response to its associated numerical value being sequential to the value of the pattern counter.

Moreover, in accordance with the techniques described herein, the scan pattern is applied to the functional unit in response to a self-test timer reaching a threshold amount of time while the idle event is detected. As elaborated above, e.g., with respect to the block 406 of FIG. 4A, the self-test timer is used to ensure that the in-field testing is not performed too frequently, as testing uses significant bandwidth of the system on chip.

An output of the functional unit in response to the scan pattern is received (block 504). By way of example, the scan controller records the output of the functional unit to the sequence of input signals (e.g., in a test data register) to enable the output of the functional unit to be analyzed. The output of the functional unit, for instance, is a sequence of output signals produced by the functional unit in response to the sequence of input signals.

A status of the functional unit with respect to the fault is output based on the output of the functional unit and an expected output (block 506). By way of example, the scan pattern is also associated with the expected output, which refers to an expected sequence of output signals that would be produced by the functional unit if the fault is not present. If the output of the functional unit deviates from the expected output, then the fault associated with the scan pattern is detected (e.g., the fault is present), and a “fail” status is generated and output. If the output of the functional unit matches the expected output, then the fault associated with the scan pattern is not detected (e.g., the fault is absent), and a “pass” status is generated and output.

In one or more implementations, an alert is generated in response to the fail status being output. By way of example, the alert identifies the detected fault as well as the functional unit and its location. In one or more implementations, the alert is logged via the BMC 132 and/or output via a user interface, such as described above at the block 436 of FIG. 4B. By generating and communicating the alert, an administrator is able to take any warranted action, such as running diagnostics and/or putting the tested SoC functional unit (or the SoC 102 itself) into a quarantine pool. By detecting the fault and generating the alert, an occurrence of silent data corruption due to in-field faults is reduced, resulting in more reliable operation of the SoC 102 and the data center 104 as a whole.

It should be understood that many variations are possible based on the disclosure herein. Although features and elements are described above in particular combinations, each feature or element is usable alone without the other features and elements or in various combinations with or without other features and elements.

The various functional units illustrated in the figures and/or described herein (including, where appropriate, the SoC 102, the data center 104, the IP element 110, the IP element 112, the microcontroller 114, the volatile memory 116, the non-volatile memory 118, the server 120, the server storage 122, and the BMC 132) are implemented in any of a variety of different manners such as hardware circuitry, software or firmware executing on a programmable processor, or any combination of two or more of hardware, software, and firmware. The methods provided are implemented in any of a variety of devices, such as a general-purpose computer, a processor, or a processor core. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit, and/or a state machine.

In one or more implementations, the methods and procedures provided herein are implemented in a computer program, software, or firmware incorporated in a non-transitory computer-readable storage medium for execution by a general-purpose computer or a processor. Examples of non-transitory computer-readable storage mediums include a read only memory (ROM), a random-access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A system on chip, comprising:
a functional unit having a defined functional role for the system on chip; and
a processor to execute instructions for an in-field self-test that causes the processor to:
apply a scan pattern associated with a fault to the functional unit during an idle event of the functional unit, the scan pattern defining a sequence of input signals;
receive an output of the functional unit in response to the scan pattern; and
output a status of the functional unit with respect to the fault based on the output of the functional unit and an expected output for the scan pattern.

2. The system on chip of claim 1, wherein applying the scan pattern to the functional unit is in response to a self-test timer reaching a threshold amount of time while the idle event is detected.

3. The system on chip of claim 1, wherein outputting the status of the functional unit with respect to the fault based on the output of the functional unit and the expected output for the scan pattern comprises:
outputting a fail status in response to the output of the functional unit deviating from the expected output; and
outputting a pass status in response to the output of the functional unit matching the expected output.

4. The system on chip of claim 3, wherein the fail status indicates the fault is present in the functional unit, and the in-field self-test further causes the processor to generate an alert in response to outputting the fail status.

5. The system on chip of claim 1, wherein the in-field self-test further causes the processor to:
copy the scan pattern from a mass storage location to a local memory of the system on chip by executing a scan pattern self-test application; and
retrieve the scan pattern from the local memory during the idle event of the functional unit.

6. The system on chip of claim 5, wherein the scan pattern self-test application is executed upon boot-up of the system on chip.

7. The system on chip of claim 1, wherein applying the scan pattern associated with the fault to the functional unit during the idle event of the functional unit comprises:
selecting the scan pattern from a plurality of scan patterns based on a value of a pattern counter, individual scan patterns of the plurality of scan patterns defining different sequences of input signals; and
executing the sequence of input signals by a scan controller of the system on chip.

8. The system on chip of claim 7, wherein receiving the output of the functional unit in response to the scan pattern comprises recording, by the scan controller, the response of the functional unit to the sequence of input signals.

9. The system on chip of claim 7, wherein the individual scan patterns of the plurality of scan patterns are associated with sequential numerical values, and wherein a numerical value associated with the scan pattern matches the value of the pattern counter.

10. The system on chip of claim 1, wherein the scan pattern is included in a scan pattern payload that is generated based on fault models received from a manufacturer of the system on chip, and wherein the in-field self-test further causes the processor to isolate the functional unit from other functional units of the system on chip in response to detecting the idle event of the functional unit.

11. A method, comprising:
detecting an idle event of a functional unit of a system on chip;
isolating the functional unit from other functional units of the system on chip in response to detecting the idle event; and
while isolating the functional unit from the other functional units of the system on chip during the idle event and responsive to a threshold amount of time having passed since completing a scan pattern self-test at the functional unit:
capturing a response of the functional unit to at least one scan pattern of a plurality of scan patterns; and
indicating a status of the functional unit with respect to a fault associated with the at least one scan pattern based on the response of the functional unit to the at least one scan pattern relative to an expected response.

12. The method of claim 11, wherein individual scan patterns of the plurality of scan patterns are associated with sequential numerical values, and the method further comprises:
tracking execution of the plurality of scan patterns across one or more idle events of the functional unit via a pattern counter.

13. The method of claim 12, wherein tracking the execution of the plurality of scan patterns across the one or more idle events of the functional unit via the pattern counter comprises:
executing the plurality of scan patterns in numerical order; and
incrementing a number value of the pattern counter after executing a scan pattern of the plurality of scan patterns at the functional unit.

14. The method of claim 12, wherein capturing the response of the functional unit to the at least one scan pattern of the plurality of scan patterns comprises:
loading an individual scan pattern of the at least one scan pattern from a local memory storing the plurality of scan patterns to a scan controller of the system on chip;
applying, by the scan controller, a series of input signals defined by the individual scan pattern to the functional unit;
recording, by the scan controller, a series of output signals of the functional unit in response to the series of input signals; and
after recording the series of output signals by the scan controller:
exiting the idle event in response to receiving a request to execute a task at the functional unit; or
loading a subsequent individual scan pattern of the at least one scan pattern to the scan controller in response to not receiving the request to execute the task at the functional unit.

15. The method of claim 11, further comprising:
copying the plurality of scan patterns from a mass storage location to a local memory of the system on chip in response to completion of a boot-up event of the system on chip; and
updating the plurality of scan patterns in the mass storage location in response to receiving new fault models.

16. A system, comprising:
a system on chip comprising an intellectual property (IP) element; and
a processor to execute instructions that cause the processor to:
detect an idle event of the IP element;
isolate the IP element from other IP elements of the system on chip in response to detecting the idle event; and
while isolating the IP element from the other IP elements of the system on chip during the idle event, perform a scan pattern self-test by:
executing at least one scan pattern of a scan pattern payload at the IP element responsive to a threshold amount of time having elapsed since previously completing the scan pattern self-test at the IP element; and
indicating a status of the IP element with respect to a fault associated with the at least one scan pattern based on an output of the IP element to the at least one scan pattern relative to an expected output.

17. The system of claim 16, wherein the threshold amount of time is determined based on a saturation of a self-test timer associated with the IP element, the self-test timer configured to reset upon completion of the scan pattern self-test.

18. The system of claim 17, wherein the completion of the scan pattern self-test comprises executing every scan pattern of the scan pattern payload over one or more idle events of the IP element.

19. The system of claim 16, wherein the instructions further cause the processor to track execution of the at least one scan pattern via a pattern counter associated with the IP element.

20. The system of claim 16, further comprising a local memory communicatively coupled to the system on chip and storing the scan pattern payload, and wherein the instructions further cause the processor to:
load an individual scan pattern of the at least one scan pattern from the local memory to the system on chip;
apply, via a scan controller of the system on chip, a sequence of input signals defined by the individual scan pattern to the IP element; and
record, by the scan controller, the output of the IP element to the individual scan pattern as a sequence of output signals.
